(19) United States
(12) Patent Application Publication
(10) Pub. No.: US 2023/0268194 A1
(43) Pub. Date: Aug. 24, 2023

(54) SUBSTRATE PROCESSING APPARATUS, AND WATERPROOFING DEVICE FOR ACOUSTIC SENSOR

(71) Applicant: EBARA CORPORATION, Tokyo (JP)

(72) Inventor: Hiroaki NISHIDA, Tokyo (JP)

(21) Appl. No.: 18/005,216

(22) PCT Filed: Jul. 9, 2021
(86) PCT No.: PCT/JP2021/025877

§ 371 Date: Jan. 12, 2023

(30) Foreign Application Priority Data
Jul. 13, 2020 (JP) 2020-120201

(51) Int. Cl. H01L 21/461; H01L 21/687; H01R 13/52; H01J 37/32

(52) U.S. Cl. CPC H01L 21/461; H01J 37/3244; H01J 37/32816; H01J 37/32853; H01L 21/68785; H01R 13/52; H01L 2021/60075

(57) ABSTRACT

A substrate processing apparatus for polishing a substrate by pressing the substrate against a polishing pad, comprises: an acoustic sensor having a sensor body that detects polishing sound of the substrate and outputs the polishing sound as an acoustic signal, and a cover member that houses the sensor body; an end point detection unit that detects an end point of polishing of the substrate from the acoustic signal; and a gas supply device that supplies a gas into the cover member so as to prevent adhesion of moisture (water droplets and water vapor) to the sensor body. The gas supply device is connected to the sensor body on an opposite side of a detection surface for the polishing sound, a groove for passing the gas from the gas supply device is formed in the cover member, and a plurality of micro openings for passing the gas from the gas supply device are formed on a waterproof sheet.

### TECHNICAL FIELD

The present invention relates to an apparatus for processing a surface of a semiconductor substrate or the like, and to a waterproofing device for an acoustic sensor for use in a substrate processing apparatus.

### BACKGROUND ART

In a manufacturing step of a semiconductor device, a polishing device for performing a polishing process on a surface of a substrate, such as a semiconductor substrate, has been widely used. In this type of polishing device, a substrate is rotated in a state in which the substrate is held by a substrate holding device called a top ring or a polishing head. In this state, the surface of the substrate is pressed against a polishing surface of a polishing pad while rotating a polishing table together with the polishing pad, and the surface of the substrate is caused to slidingly contact the polishing surface under the presence of a polishing liquid, thereby polishing the surface of the substrate.

When a film thickness of the substrate surface reaches a predetermined value by polishing the substrate surface, or when appearance of a foundation layer (for example, a stopper layer) is detected, the substrate polishing process is ended. In such a polishing process, it is required to accurately control the film thickness of the substrate surface after the process. Various methods have been studied to detect an end of polishing of the substrate, and, for example, detection of a change in polishing sound using an acoustic sensor has been proposed.

For example, a control device described in Japanese Patent Laid-Open No. 2017-163100 is configured to detect a power spectrum of polishing sound from a substrate, using an acoustic sensor, calculate an S/N ratio per unit time from the amount of change in the power spectrum, and, when the obtained S/N ratio exceeds a threshold value, determine that polishing of the substrate comes to an end point.

### SUMMARY OF INVENTION

In order to detect the end point of polishing of the substrate using the acoustic sensor, it is necessary to bring the acoustic sensor as close as possible to the substrate being polished. Therefore, the vicinity of the acoustic sensor is exposed to high humidity due to an abrasive liquid used during polishing of the substrate and a cleaning liquid used after polishing of the substrate, and consequently a detection error may occur due to adhesion of water droplets to the acoustic sensor, or condensation of water vapor.

In order to prevent such a situation, it is considered to seal the acoustic sensor with a waterproof housing, but polishing sound from the substrate being polished may be partially blocked by the housing, and performance of measuring the polishing sound may deteriorate. Moreover, if condensation occurs inside the housing, water droplets adhere to the acoustic sensor, or water vapor condenses, and may cause a detection error.

Furthermore, when a portion of the housing that holds the acoustic sensor (the vicinity of a detection unit of the acoustic sensor) is made open, and the portion is covered with a waterproof sheet (waterproof film), it is possible to improve the waterproof performance while allowing passage of polishing sound, but moisture in the vicinity of the acoustic sensor cannot be completely prevented. Therefore, if the acoustic sensor is put in a high humidity environment during the long-time use, moisture accumulates or condenses inside the housing, water droplets adhere to the acoustic sensor, or water vapor condenses, and may cause a detection error.

One aspect of the present invention is a substrate processing apparatus for polishing a substrate by pressing the substrate against a polishing pad, the substrate processing apparatus including: a substrate holding device that rotatably holds the substrate; an acoustic sensor having a sensor body that detects polishing sound of the substrate and outputs the polishing sound as an acoustic signal, and a cover member that houses the sensor body; an end point detection unit that detects an end point of polishing of the substrate from the acoustic signal; and a gas supply device that supplies a gas into the cover member so as to prevent adhesion of moisture to the sensor body.

One aspect of the present invention is a waterproofing device for preventing adhesion of water droplets to a sensor body that detects polishing sound of a substrate and outputs the polishing sound as an acoustic signal, in a substrate processing apparatus for polishing the substrate by pressing the substrate against a polishing pad, the waterproofing device including: a cover member that houses the sensor body; and a gas supply device that supplies a gas into the cover member so as to prevent adhesion of moisture to the sensor body.

### BRIEF DESCRIPTION OF DRAWINGS

FIG. 1 is a plan view schematically showing a configuration of a substrate processing apparatus according to one embodiment of the present invention.

FIG. 2 is a perspective view schematically showing one embodiment of a substrate polishing unit.

FIG. 3 is a side view showing a configuration of the substrate polishing unit.

FIG. 4 is an explanatory view showing one example of a configuration of a control device.

FIG. 5 is a partial sectional view partially showing the configuration of the substrate polishing unit.

FIG. 6 is a side view showing a configuration of a gas supply device.

FIG. 7 is a perspective view showing a configuration of an acoustic sensor holding mechanism.

FIG. 8 is a perspective sectional view showing a configuration of an acoustic sensor.

FIG. 9 is an explanatory view showing an internal configuration of the acoustic sensor, wherein FIG. 9(a) shows the configuration seen from a detection surface, and FIG. 9(b) shows the configuration seen from a side surface.

FIG. 10 is a side view showing another example of the configuration of the gas supply device.

### DESCRIPTION OF EMBODIMENT

Hereinafter, a substrate processing apparatus according to one embodiment of the present invention is described with reference to the drawings. Note that the same or equivalent components are designated with the same reference signs, and redundant explanations are omitted.

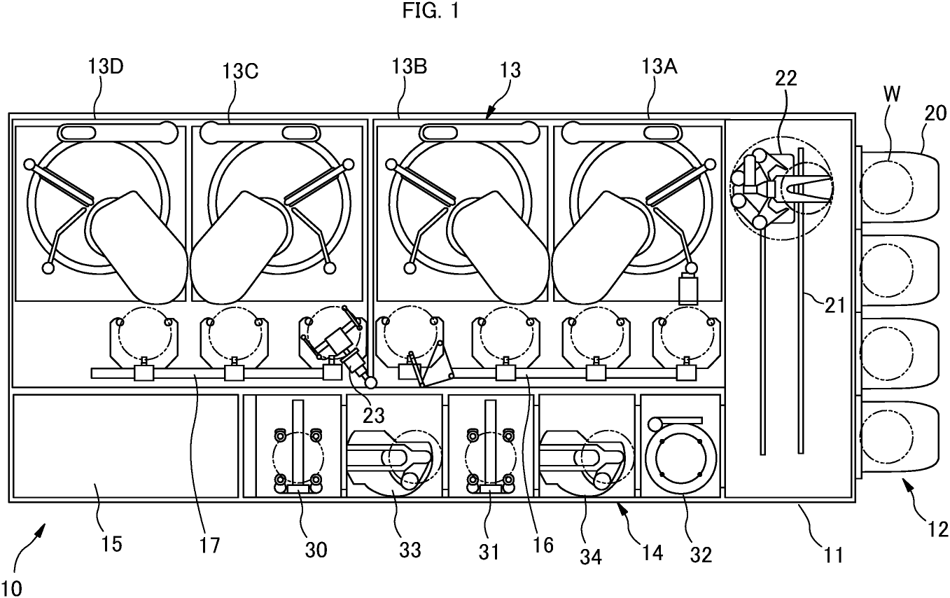

FIG. 1 is a plan view showing the entire configuration of a substrate processing apparatus. A substrate processing apparatus 10 is parted into a loading/unloading section 12, a polishing section 13, and a cleaning section 14 which are arranged in a rectangular housing 11. Moreover, the substrate processing apparatus 10 has a control device 15 that controls operations of processes, such as substrate transport, polishing, and cleaning.

The loading/unloading section 12 has a plurality of front loading units 20, a traveling mechanism 21, and a transport robot 22. A substrate cassette for storing a number of substrates (wafers) W is placed on each of the front loading units 20. The transport robot 22 has two upper and lower hands, and moves on the traveling mechanism 21 to perform operations for taking out a substrate W in the substrate cassette placed on the front loading unit 20 and feeding the substrate W to the polishing section 13, and returning the processed substrate fed from the cleaning section 14 to the substrate cassette.

The polishing section 13 is an area in which polishing of the substrate (a flattening process) is performed, and has a plurality of polishing units 13A to 13D arranged along a longitudinal direction of the substrate processing apparatus. Each polishing unit has: a top ring for polishing the substrate W on a polishing table while pressing the substrate W against a polishing pad; a liquid supply nozzle for supplying a liquid, such as a polishing liquid and purified water, to the polishing pad; a dresser for dressing a polishing surface of the polishing pad; and an atomizer for spraying a mixed fluid of liquid and gas, or a mist of liquid onto the polishing surface to wash away polishing dust and abrasive grains remaining on the polishing surface.

Provided between the polishing section 13 and the cleaning section 14 are first and second linear transporters 16, 17 as transporting mechanisms for transporting the substrates W. The first linear transporter 16 is movable among a first position for receiving the substrate W from the loading/unloading section 12, second and third positions for passing the substrate W between the polishing units 13A and 13B, and a fourth position for passing the substrate W to the second linear transporter 17.

The second linear transporter 17 is movable among a fifth position for receiving the substrate W from the first linear transporter 16, and sixth and seventh positions for passing the substrate W between the polishing units 13C and 13D. Provided between these transporters 16, 17 is a swing transporter 23 for sending the substrate W from the fourth position or the fifth position to the cleaning section 14, and from the fourth position to the fifth position.

The cleaning section 14 has a first substrate cleaning device 30, a second substrate cleaning device 31, a substrate drying device 32, and transport robots 33, 34 for passing the substrate between these devices. The substrate W which has undergone a polishing process in the polishing unit is cleaned by the first substrate cleaning device 30 (primary cleaning), and then further cleaned by the second substrate cleaning device 31 (final cleaning). The cleaned substrate is transported from the second substrate cleaning device 31 to the substrate drying device 32, and spin-dried. The dried substrate W is taken out by the transport robot 22, and returned to the substrate cassette placed on the front loading unit 20.

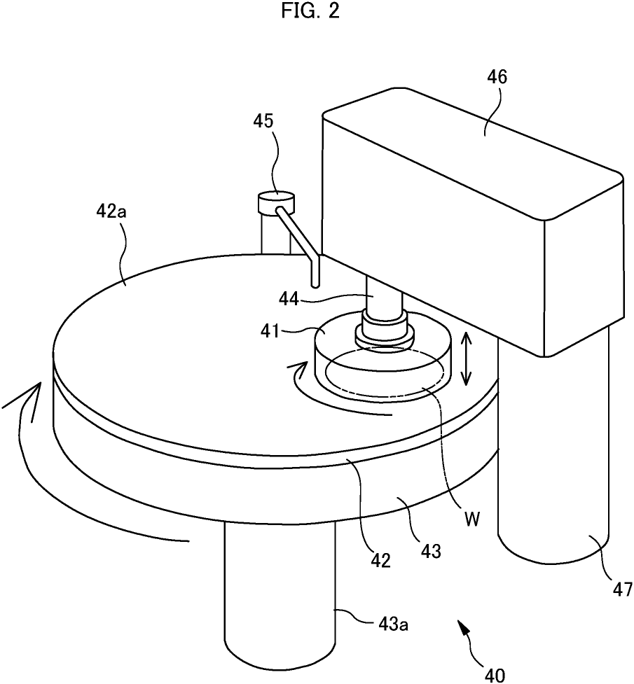

FIG. 2 is a perspective view schematically showing the configuration of the polishing units 13A to 13D. A polishing unit 40 has: a polishing pad 42 with a top surface as a polishing surface 42a; a polishing table 43 to which the polishing pad 42 is attached, a top ring 41 that holds a substrate W, such as a wafer, as an object to be polished, and brings the substrate W into slidingly contact with the polishing surface 42a to polish the substrate W; and a dresser for dressing the polishing surface 42a. The polishing table 43 is coupled to a motor, not shown, and the polishing table 43 and the polishing pad 42 rotate in a direction indicated by an arrow in FIG. 2.

The top ring 41 is coupled to a lower end of a drive axis 44 protruding downward from a top ring head cover 46 covering a driving mechanism, and a bottom surface of the top ring 41 constitutes a substrate holding surface for holding the substrate by vacuum suction, etc. Moreover, the top ring 41 is movable between a polishing position located above the polishing table 43 and a substrate passing position on a side of the polishing table by a swing motion of a revolving arm, not shown, caused by rotation of a swing axis 47.

The top ring 41 is configured to hold the substrate W on a lower surface thereof by vacuum suction. Further, the polishing table 43 is rotatable about a table axis 43a by the motor, not shown. The top ring 41 and the polishing table 43 rotate in the direction indicated by the arrow, and, in this state, the top ring 41 presses the substrate W against the polishing surface 42a on the upper side of the polishing pad 42 held on the polishing table 43. Under the presence of a polishing liquid supplied onto the polishing pad 42 from a polishing liquid supply nozzle 45, the substrate W slidingly contacts the polishing pad 42, and is polished.

The substrate W is constituted by an upper layer that is a metal or silicon oxide film for example, and a lower layer that is a silicon film for example. Since the materials of the upper layer and the lower layer of the substrate W are different, when polishing of the upper layer of the substrate W proceeds and the lower layer is exposed, an acoustic spectrum (power spectrum) of polishing sound generated by the substrate W and the polishing pad 42 changes. It is noted that the configuration of the substrate W of the present invention is not limited to this, and various materials for use in a semiconductor chip manufacturing process can be used.

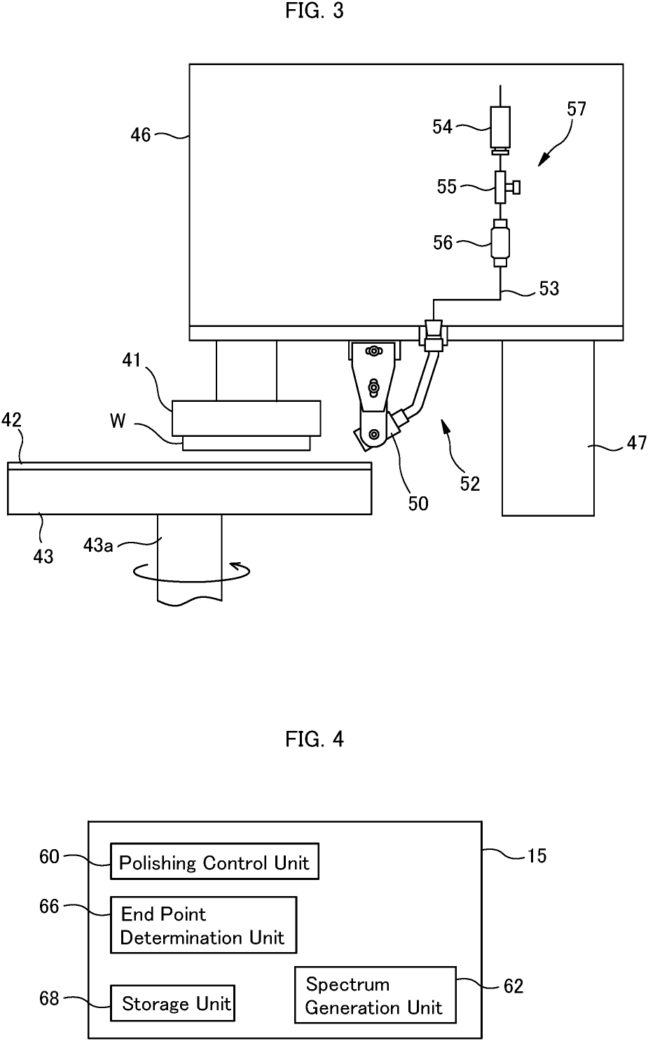

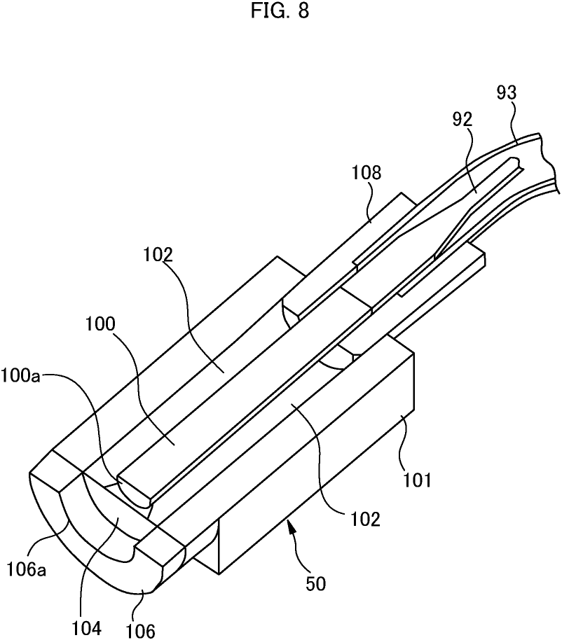

In FIG. 3, an acoustic sensor 50 for detecting polishing sound from the substrate W is disposed in the vicinity of the top ring 41. For example, an ultrasonic microphone (see reference numeral 100 in FIG. 8) is used for the acoustic sensor 50, and the acoustic sensor 50 detects polishing sound resulting from friction between the polishing pad 42 and the substrate W pressed by the top ring 41, and outputs the polishing sound as an electric signal (acoustic signal). The acoustic sensor 50 is connected to the control device 15 (see FIG. 4), and the acoustic signal corresponding to the polishing sound of the substrate W is transmitted to the control device 15. Alternatively, an acoustic emission sensor may be used as the acoustic sensor 50.

The acoustic sensor 50 is secured to a bottom part of the top ring head cover 46 by a holding mechanism 52. Moreover, provided inside the top ring head cover 46 are: a pipe 53 for supplying an inert gas such as air or nitrogen to the acoustic sensor 50; a solenoid valve 54; a flow rate adjustment valve 55; and a clean filter 56, which constitute a gas supply device 57. The detailed configurations of the holding mechanism 52 and the gas supply device 57 will be described later.

FIG. 4 is an explanatory view showing one example of the configuration of the control device 15. The control device 15 is a widely-used computer device for example, and has a CPU, memory in which a control program is stored, an input unit, a display unit, etc. The control device 15 operates as a polishing control unit 60, a spectrum generation unit 62, and an end point determination unit 66 by activating the control program stored in the memory, thereby comprehensively controlling operations of the polishing unit 40. Note that the control device 15 is not limited to the configuration shown in FIG. 4, and also has a configuration for controlling operations of other elements (for example, the loading/unloading section 12 and the cleaning section 14) of the substrate processing apparatus 10, and a later-described configuration for controlling a supply of gas into the acoustic sensor 50.

A control program for controlling an operation of the substrate processing apparatus 10 may be pre-installed in the computer constituting the control device 15, or stored in a storage medium such as CD-ROM and DVD-ROM, or may be installed in the control device 15 through the Internet.

The polishing control unit 60 controls operations of the top ring 41, the polishing table 43, etc. constituting the polishing unit 40, and performs the polishing process on the substrate W held on the top ring 41.

The spectrum generation unit 62 performs a fast Fourier transform (FFT) on data of the acoustic signal transmitted from the acoustic sensor 50 (the signal resulting from friction sound of the substrate W pressed by the polishing pad 42) to extract a frequency component and intensity thereof, and outputs the frequency component and the intensity as a power spectrum (a sound pressure level against the frequency) of the acoustic signal of the substrate W.

The end point determination unit 66 monitors the power spectrum in a predetermined frequency band (monitoring range), and determines whether or not there is certain change in the power spectrum in the monitoring range. The end point determination unit 66 transmits, upon detection of the change in the power spectrum in the monitoring range, a signal indicating an end of polishing of the substrate to the polishing control unit 60.

A storage unit 68 is, for example, a non-volatile memory device in which information about the signal received from the acoustic sensor 50, information about the power spectrum generated in the spectrum generation unit 62, and information such as a monitoring range determined for each type of the layers constituting the substrate W are stored, and the information is appropriately read out.

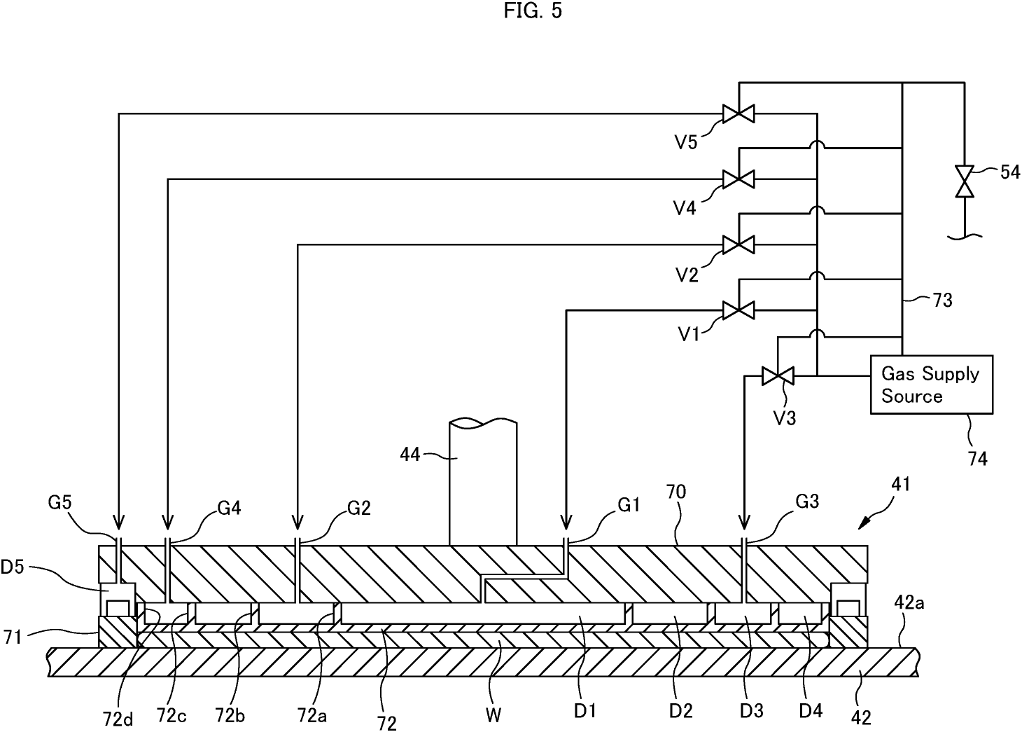

As shown in FIG. 5, the top ring 41 has a head body 70 secured to a lower end of a top ring shaft 44, a retainer ring 71 supporting a side edge of the substrate W, and a flexible elastic membrane 72 for pressing the substrate W against the polishing surface of the polishing pad 42. The retainer ring 71 is disposed to surround the substrate W, and is coupled to the head body 70. The elastic membrane 72 is attached to the head body 70 so as to cover a lower surface of the head body 70.

The head body 70 is formed by, for example, a resin material such as engineering plastic (for example, PEEK), and the elastic membrane 72 is formed by, for example, a rubber material having excellent strength and durability, such as ethylene propylene rubber (EPDM), polyurethane rubber, and silicone rubber. The head body 70 and the retainer ring 71 constituting the top ring 41 are configured to integrally rotate with the rotation of a top ring shaft 47.

The retainer ring 71 is disposed to surround the head body 70 and the elastic membrane 72. This retainer ring 71 is a member formed by a ring-shaped resin material that contacts the polishing surface 42a of the polishing pad 42, and holds the polishing pad 42 so that the polishing pad 42 in contact with an outer periphery of the substrate W is horizontally retained. Moreover, the retainer ring 71 is disposed to surround an outer peripheral edge of the substrate W held by the head body 70, and supports the outer peripheral edge of the substrate W so that the substrate W being polished does not jump out from the top ring 41.

A ring-shaped retainer ring pressing mechanism, not shown, is coupled to an upper surface of the retainer ring 71, and a uniform downward load is applied over the entire upper surface of the retainer ring 71. Consequently, a lower surface of the retainer ring 71 is pressed against the polishing surface 42a of the polishing pad 42.

The elastic membrane 72 has a plurality of (four in FIG. 4) ring-shaped peripheral walls 72a, 72b, 72c, 72d disposed concentrically. The plurality of peripheral walls 72a to 72d form a circular first pressure chamber D1 located at the center, and ring-shaped second, third, and fourth pressure chambers D2, D3, D4, between an upper surface of the elastic membrane 72 and the lower surface of the head body 70.

A flow passage G1 communicating with the central first pressure chamber D1, and flow passages G2 to G4 communicating with the second to fourth pressure chambers D2 to D4 are formed in the head body 70. These flow passages G1 to G4 are connected to a gas supply source 74 through gas lines, respectively. In each gas line, an air-operated valve (any one of V1 to V4) and a pressure controller, not shown, are installed. The air-operated valves V1 to V4 are valves which are switched on and off depending on the magnitude of air pressure, and on and off are switched by the control device 15 through a switch line 73 (which is provided separately from the gas lines) from the gas supply source 74. Note that on and off of the air-operated valves V1 to V4 may be controlled by providing another gas supply source separately from the gas supply source 74.

A retainer pressure chamber D5 is formed immediately above the retainer ring 71, and the retainer pressure chamber D5 is connected to the gas supply source 74 through a flow passage G5 formed in the head body 70, and a gas line in which an air-operated valve V5 and a pressure controller, not shown, are installed. The pressure controllers installed in the respective gas lines have a pressure adjustment function for adjusting the pressure of pressure gas supplied from the gas supply source 74 to the pressure chambers D1 to D4 and the retainer pressure chamber D5. Activation of the pressure controllers and the air-operated valves V1 to V5 is controlled by the control device 15. Moreover, the gas supply source 74 is connected to the solenoid valve 54 of the gas supply mechanism 57 through the switch line 73, and the solenoid valve 54 is operated by the control device 15.

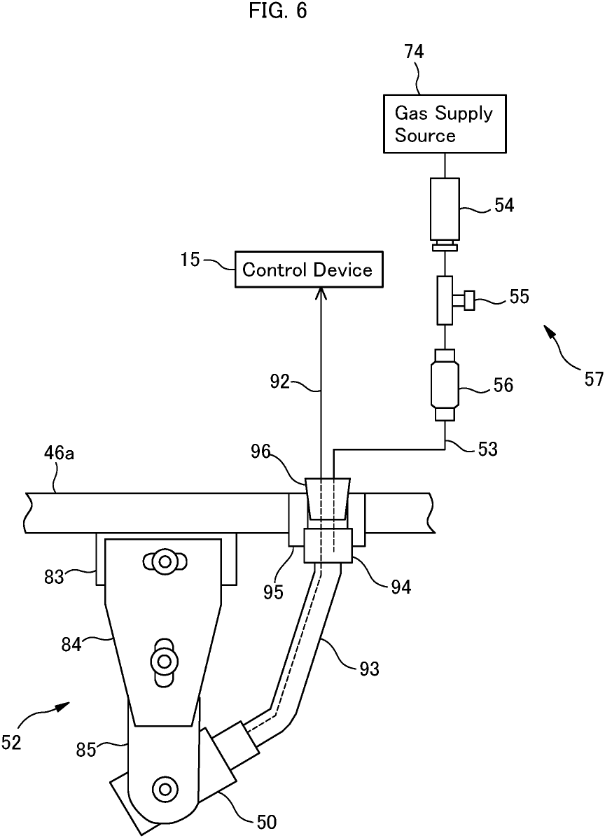

In FIG. 6, the acoustic sensor 50 is secured to the bottom part of the top ring head cover 46 by the holding mechanism 52. The holding mechanism 52 is constituted by a cover mounting member 83, a support plate 84, and a bracket 85. The acoustic sensor 50 is connected to a joint 94 through a tube 93 that houses the pipe 53 for air, and wiring 92 from the acoustic sensor 50. The joint 94 is inserted into a support part 95 attached to the bottom part 46a of the top ring head cover 46, thereby securing the joint 94 to the bottom part of the top ring head cover 46.

Another end of the support part 95 attached to the top ring head cover 46 is sealed by a seal member 96, thereby preventing the inside of the top ring head cover 46 from being exposed to outside air. Through-holes for passing the wiring 92 from the acoustic sensor 50 are formed in the joint 94 and the seal member 96, thereby electrically connecting the acoustic sensor 50 to the control device 15. Moreover, since the inside of the top ring head cover 46 and the inside of the acoustic sensor 50 are shielded from each other by the seal member 96, the gas supplied to the acoustic sensor 50 is prevented from flowing back into the top ring head cover 46, and the supplied gas is efficiently supplied to the sensor body (ultrasonic microphone).

It is noted that, for the seal member 96, for example, a rubber plug as an elastic body is preferably used, but there is no particular limitation for the member as long as the member can seal the gas, and, for example, a closing part provided with a sealing part such as an O-ring, and a caulking material may be used.

The gas supply device 57 is installed so as to supply the gas for removing water droplets that are likely to adhere to the inside of the acoustic sensor 50, and is constituted by the solenoid valve 54, the flow rate adjustment valve 55, and the clean filter 56, which are secured to the inside of the top ring head cover 46.

The solenoid valve 54 is connected to the gas supply source 74, and is operated by the control device 15 to turn on and off the supply of gas (for example, nitrogen gas) to the acoustic sensor 50. The flow rate adjustment valve 55 is, for example, a speed controller with a dial, and adjusts the supply amount of the gas to the acoustic sensor 50 by turning the dial when the apparatus is stopped (for example, during maintenance). Alternatively, the adjustment of the supply amount by the flow rate adjustment valve 55 may be configured to be performed automatically. The clean filter 56 removes impurities such as particles contained in the gas supplied from the gas supply source 74, and prevents contamination of foreign substances into the acoustic sensor 50. Moreover, the holder 94 and the seal member 96 are formed with the through-holes for passing the gas pipe 53 from the acoustic sensor 50.

Thus, by disposing, inside the top ring head cover 46, the gas supply device 57 for supplying the gas to the acoustic sensor 50, it is possible to configure the space-saving, low-cost device for supplying the gas to the acoustic sensor.

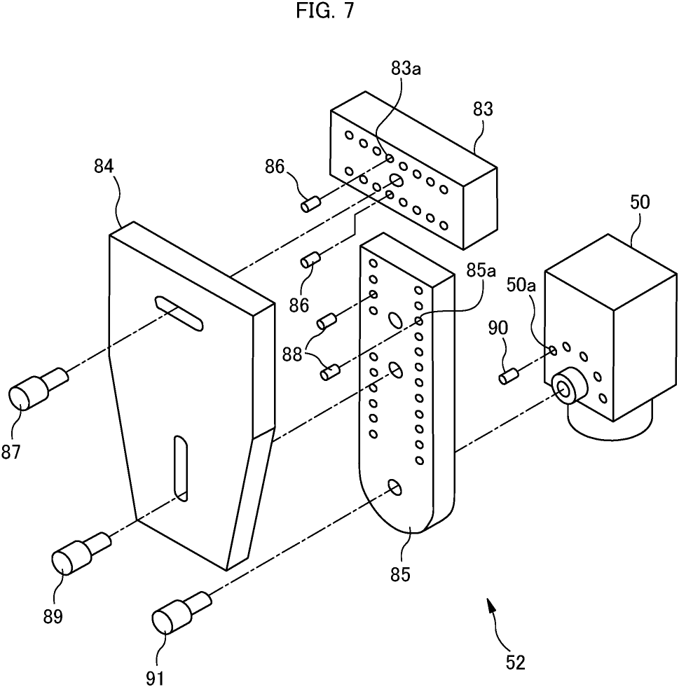

In FIG. 6 and FIG. 7, the cover mounting member 83 is secured to the bottom part 46a of the top ring head cover 46, and has a plurality of positioning holes 83a formed at constant intervals. The support plate 84 has a plurality of positioning holes formed at constant intervals on a surface (rear surface in FIG. 7) which contacts the cover mounting member 83, and the mounting position of the support plate 84 with respect to the cover mounting member 83 can be appropriately changed by inserting positioning pins 86 into the positioning holes of the cover mounting member 83 and the support plate 84. Further, the support plate 84 is secured to the cover mounting member 83 with a bolt 87.

The bracket 85 has a plurality of positioning holes 85a formed at constant intervals on a surface (front surface in FIG. 7) which contacts the support plate 84. Similarly, a plurality of positioning holes are also formed at constant intervals on a corresponding surface (rear surface in FIG. 7) of the support plate 84. The mounting position of the bracket 85 with respect to the support plate 84 can be appropriately changed by inserting positioning pins 88 into the positioning holes of the support plate 84 and the bracket 85. Further, the bracket 85 is secured to the support plate 84 with a bolt 89.

Furthermore, the acoustic sensor 50 has a plurality of positioning holes 50a formed concentrically at constant intervals on a surface (front surface in FIG. 7) which contracts the bracket 85, and the positioning holes 50a correspond to the plurality of positioning holes formed concentrically at constant intervals on a corresponding surface (rear surface in FIG. 7) of the bracket 85. The mounting angle of the acoustic sensor 50 can be adjusted by inserting a positioning pin 90 into the positioning holes of the acoustic sensor 50 and the bracket 85. Further, the acoustic sensor 50 is secured to the bracket 85 with a bolt 91.

Thus, by fixing the mounting position and the mounting angle of the acoustic sensor 50 with the pins, even when the acoustic sensor 50 is temporarily detached, for example, during maintenance of the apparatus, the acoustic sensor 50 can be easily restored into the original state.

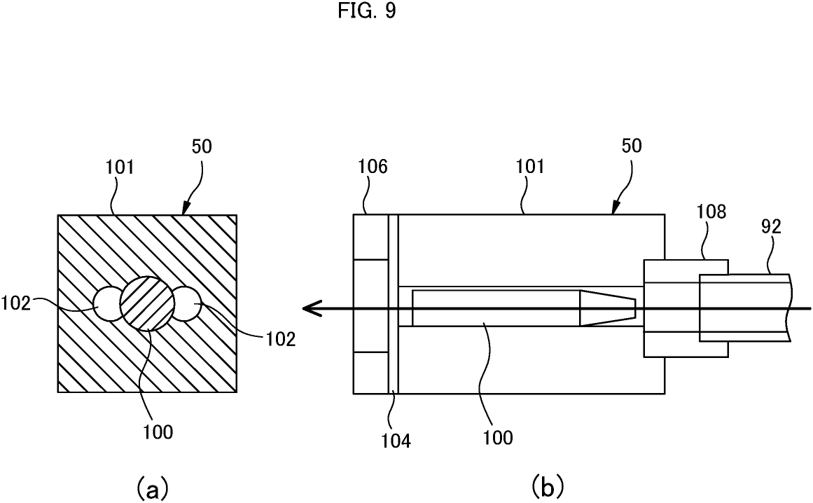

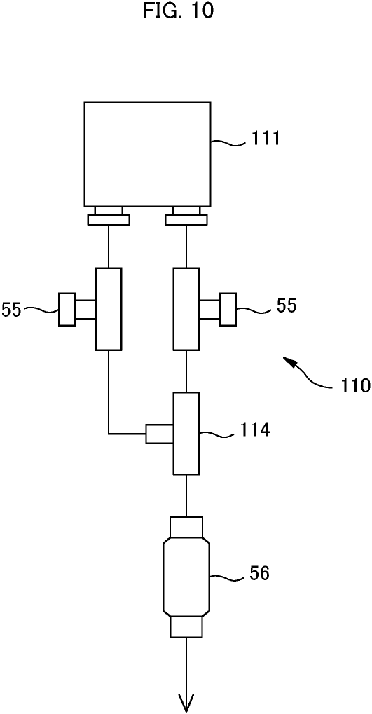

As shown in FIG. 8 and FIG. 9, the acoustic sensor 50 has a sensor body 100 that detects polishing sound from the substrate W, and a sensor cover 101, and the sensor body 100 is held in a state of being inserted into the sensor cover 101. A waterproof sheet 104 is disposed in front of a detection surface 100a of the sensor body 100, and secured by a front cover 106 with an opening 106a, which is further provided in front of the waterproof sheet 104, in a state in which the waterproof sheet 104 is interposed between the sensor cover 101 and the front cover 106.

The waterproof sheet 104 is, for example, a fluorocarbon resin sheet formed with a number of micro openings, and can block entry of water droplets into the acoustic sensor 50, without blocking polishing sound from the substrate W.

The wiring 92 is connected through a connector to a surface of the sensor body 100 on the opposite side of the detection surface. Moreover, a joint 108 that houses a portion of the wiring 92 is inserted into the opening formed on the sensor cover 101, and the wiring 92 is protected from outside air by the joint 108 and the tube 93.

The waterproof sheet 104 disposed on the detection surface side of the acoustic sensor 50 can prevent entry of water droplets, but cannot completely prevent entry of water vapor smaller than water droplets. Further, since the inside of the polishing unit 40 needs to be kept in a moist state to prevent the polishing liquid from drying out, there is a possibility that water vapor accumulates and condenses in the acoustic sensor 50, and consequently polishing sound detection performance of the acoustic sensor 50 decreases, or the sensor breaks down.

Therefore, in the substrate processing apparatus according to the present embodiment, by supplying the gas into the acoustic sensor 50 through the gas supply device 57, water vapor is removed to the outside by ventilation of gas through the inside of the acoustic sensor 50, and water droplets and water vapor are prevented from entering into the acoustic sensor 50 from the outside. Consequently, it is possible to prevent adhesion of moisture to the sensor body 100. Here, adhesion of moisture means adhesion of water droplets to the sensor body 100, and condensation of water vapor on the front surface of the sensor body 100.

In the acoustic sensor 50, a recess for housing the sensor body 100, and a pair of grooves 102 on both side of the recess are formed. When the gas from the gas supply source 74 is supplied through the pipe 53 in the tube 93 from the surface of the acoustic sensor 50, on the opposite side of the detection surface, the gas flows in through the grooves 102 of the sensor body 100, and passes through the micro openings of the waterproof sheet 104 to the outside of the sensor body 50 (see an arrow in FIG. 9(b)). Consequently, it is possible to pass the gas through the inside of the acoustic sensor 50.

The supply of the gas into the acoustic sensor 50 is performed at a timing after the polishing process on the substrate W, or before staring the polishing process on the substrate W. By stopping the supply of the gas into the acoustic sensor 50 during the polishing process on the substrate W (more specifically, during detection of polishing sound by the acoustic sensor 50), it is possible to prevent a decrease in the polishing sound detection performance of the acoustic sensor 50 due to the supply of the gas.

In the above embodiment, the configuration having one flow rate adjustment valve 55 is described, but the present invention is not limited to this, and, for example, as shown in FIG. 10, two (or more) flow rate adjustment valves 55 may be provided and connected in parallel to a solenoid valve 111 so as to cause the gas from the flow rate adjustment valves 55 to flow through a joint 114 to the clean filter 56. Consequently, it is possible to accurately control the supply amount of the gas to the acoustic sensor 50. Moreover, even if one of the flow rate adjustment valves 55 has a trouble, it is possible to perform ventilation by passing the gas through the inside of the acoustic sensor 50 using another flow rate adjustment valve 55.

In the above embodiment, ventilation is performed by passing the gas through the inside of the acoustic sensor 50 at a timing after polishing, but the present invention is not limited to this, and, for example, ventilation may be performed at constant time intervals. Further, ventilation may be performed during the substrate polishing process, but there is a possibility of a decrease in the detection performance of the acoustic sensor 50 due to a flow of the gas, and therefore, when ventilation is performed during the substrate polishing process, it is preferred to reduce the supply amount of the gas (or stop the supply of the gas during measurement of polishing sound by the acoustic sensor 50).

In the above embodiment, the supply of the gas to the acoustic sensor 50 is performed from the opposite side of the detection surface 100a (from the surface on the waterproof sheet 104 side), but, since the inside space of the sensor body is in a semi-sealed state by the waterproof sheet 104, the seal member 96, the joint 108 and the tube 93, the gas may be supplied from the front or a side of the detection surface 100a.

The above embodiment is described for the purpose of allowing persons with ordinary knowledge in the technical field to which the present invention belongs to implement the prevent invention. It is obvious for those skilled in the art to make various modifications to the above embodiment, and the technical concept of the present invention is also applicable to other embodiments. The present invention should be interpreted in the broadest scope consistent with the technical concept defined by the claims, without being limited to the described embodiment.

1. A substrate processing apparatus for polishing a substrate by pressing the substrate against a polishing pad, the substrate processing apparatus comprising:
a substrate holding device that rotatably holds the substrate;
an acoustic sensor comprising a sensor body that detects polishing sound of the substrate and outputs the polishing sound as an acoustic signal, and a cover member that houses the sensor body;
an end point detection unit that detects an end point of polishing of the substrate from the acoustic signal; and
a gas supply device that supplies a gas into the cover member so as to prevent adhesion of moisture to the sensor body.

2. The substrate processing apparatus according to claim 1, wherein the gas supply device comprises: a gas supply source that supplies the gas; a switching unit that turns on and off a supply of the gas from the gas supply source to the acoustic sensor; an adjustment unit that adjusts a supply amount of the gas; and a filter for removing foreign substances from the gas to be supplied into the acoustic sensor.

3. The substrate processing apparatus according to claim 2, wherein the substrate holding device comprises: an elastic membrane that forms a plurality of pressure chambers for pressing the substrate; a head body to which the elastic membrane is attached; a retainer ring disposed to surround the substrate; and a pressure control unit that controls pressure in the plurality of pressure chambers by supplying the gas from the gas supply source.

4. The substrate processing apparatus according to claim 1, wherein a waterproof sheet for preventing entry of water droplets into the cover member is provided on a detection surface side of the sensor body.

5. The substrate processing apparatus according to claim 4, wherein
the gas supply device is connected to the cover member so as to supply the gas into the cover member,
the cover member has a groove for passing the gas from the gas supply device, and
the waterproof sheet is formed with a plurality of micro openings for passing the gas from the gas supply device.

6. The substrate processing apparatus according to claim 1, comprising:
a support member that supports the substrate holding device; and
a holding mechanism that is secured to the support member, and holds the acoustic sensor, wherein
the acoustic sensor is capable of adjusting a mounting position and a mounting angle with respect to the polishing pad, through a plurality of positioning holes formed at constant intervals, and a pin.

7. A waterproofing device for preventing adhesion of moisture to a sensor body that detects polishing sound of a substrate and outputs the polishing sound as an acoustic signal, in a substrate processing apparatus for polishing the substrate by pressing the substrate against a polishing pad, the waterproofing device comprising:
a cover member that houses the sensor body; and
a gas supply device that supplies a gas into the cover member so as to prevent adhesion of water droplets to the sensor body.
